(19) United States
(12) Patent Application Publication
(10) Pub. No.: US 2015/0069600 A1
(43) Pub. Date: Mar. 12, 2015

(54) Embedded Silver Nanomaterials into Die Backside to Enhance Package Performance and Reliability

(71) Applicant: Texas Instruments Incorporated, Dallas, TX (US)

(72) Inventor: Rongwei Zhang, Richardson, TX (US)

(73) Assignee: Texas Instruments Incorporated, Dallas, TX (US)

(21) Appl. No.: 14/024,840

(22) Filed: Sep. 12, 2013

(51) Int. Cl. H01L 23/48; H01L 21/78

(52) U.S. Cl. CPC H01L 23/48; H01L 21/78
USPC 257/734; 438/113

(57) ABSTRACT

A method and apparatus for enhancing the electrical and thermal performance of semiconductor packages effectively, especially for laminated packages, where sinterable materials cannot be used. The concept of this invention is to embed silver or silver-coated nanomaterials, which can be nanoparticles, nanoflakes, nanowires etc., into die backside to improve the interface between die and die attach materials, thus enhancing electrical and thermal performance through sintering and enhancing reliability by improving adhesion.

### FIELD OF THE INVENTION

The invention described herein relates generally to semiconductor device packaging and associated die attachment methods. In particular, the invention relates to cost effective and delamination resistant packages and packaging methods that provide better electrical and thermal performance when implemented in molded packages. The principles herein are also applicable to other semiconductor packages and devices.

### BACKGROUND OF THE INVENTION

The present invention relates generally to the packaging of integrated circuits (ICs). More particularly, the interface between die and die attach materials is engineered to reduce the delamination between die and die attach pad and improve electrical and thermal performance, thus enhancing the package reliability.

There are a number of conventional processes for packaging integrated circuit (IC) dice. By way of example, many IC packages utilize a metallic lead frame. The lead frame typically includes a plurality of leads or contacts, and optionally a die attach pad (paddle) upon which a die may be physically attached by means of a suitable adhesive material. The die is typically electrically connected to the lead frame leads by appropriate connectors such as bonding wires. In general, the die and portions of the lead frame are encapsulated with a molding material to protect the electrical connections and the delicate electrical components on the active side of the die.

During testing and operation, packages may be repeatedly exposed to temperature cycling and other environmental stresses. By way of example, some testing protocols require cycling between temperatures as high as 150° C. and as low as −65° C. Such extreme changes in temperature may lead to delamination of the die from the die attach pad, which in turn may cause poor electrical and thermal performance, the shearing of wire bonds attached to the bond pad on die surface and other problems.

In view of the foregoing, there are continuing efforts to reduce the probability of die delamination and other damages in IC packages.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to a more detailed description that is presented later.

In accordance with an embodiment of the present invention, an apparatus is provided. The apparatus comprises; a semiconductor die, having a top side and a backside; a plurality of cavities in the back side of the semiconductor die, wherein each of the plurality of cavities contains an embedded silver structure; a substrate, having a top side and a backside; a substantially uniform layer of silver filled die attach adhesive on the top side of the substrate; wherein the backside of integrated circuit die is positioned on die attach adhesive while maintaining the top surface of the die in a parallel with the top surface of the substrate; and wherein the semiconductor die is mechanically attached to the substrate by sintering the silver particles embedded in backside of die to the silver in die attach adhesive.

In accordance with an another embodiment of the present invention, a method of attaching a semiconductor die to a substrate, comprising the steps; providing a semiconductor wafer containing integrated circuits, wherein the wafer has a top side and a backside; printing an ink containing silver particles to the back side of the wafer; etching a plurality of cavities on the backside of the wafers using metal assisted chemical etching to embed silver particles in the plurality of cavities in the backside of the wafer; separating the semiconductor wafer into individual integrated circuit die; providing a substrate, having a top side and a backside; applying a substantially uniform layer of silver particle filled adhesive to the top side of the substrate; positioning the backside of integrated circuit die on the die attach adhesive while maintaining the top surface of the die in a parallel with the top surface of the substrate; and sintering the silver particles embedded in backside of die to the silver in die attach adhesive to mechanically attach the integrated circuit die to the substrate.

### DESCRIPTION OF THE VIEWS OF THE DRAWING

FIG. 1 is a cross sectional view, including an expanded view of area of interest of a die mounted onto a lead frame or a laminated substrate in accordance with an embodiment of this invention.

FIG. 2 through FIG. 4 are illustrations of steps in the fabrication of a wafer formed according to an embodiment of this invention.

FIG. 5 is an illustration of the metal-assisted chemical etching of localized regions in a silicon wafer.

FIG. 6 is a flow diagram of the process used to to engineer the die backside and mount the die to a substrate (leadframe or laminated substrate) according to an embodiment of this invention.

In the drawings, like reference numerals are sometimes used to designate like structural elements. It should also be appreciated that the depictions in the figures are diagrammatic and not to scale.

### DETAILED DESCRIPTION OF EXAMPLE EMBODIMENTS

The present invention is described with reference to the attached figures. The figures are not drawn to scale and they are provided merely to illustrate the invention. Several aspects of the invention are described below with reference to example applications for illustration. It should be understood that numerous specific details, relationships, and methods are set forth to provide an understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

The The present invention relates generally to the packaging of integrated circuits. As explained in the background section, the testing and operation of an integrated circuit (IC) package may subject the package to temperature extremes and other stresses. Such stresses may cause delamination and degrade the performance of the package. The present invention provides a semiconductor package and a method designed to help counteract such stresses and to reduce delamination and improve electrical and thermal performance.

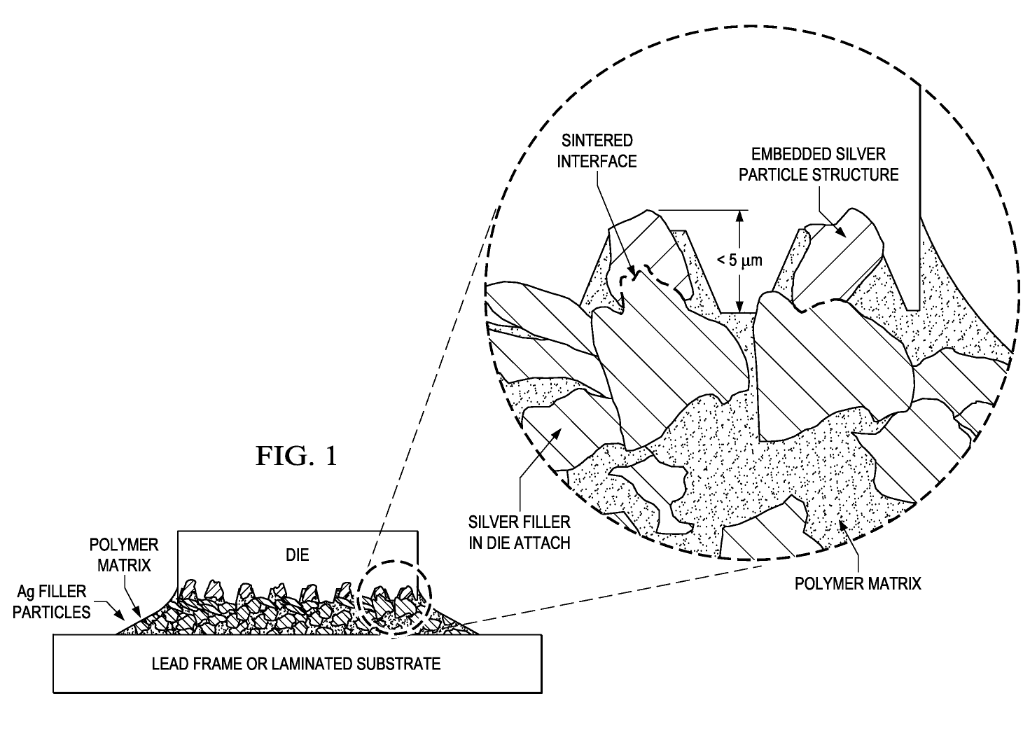

Referring next to FIG. 1, an improved packaging structure design in accordance with one aspect of the invention will be described. FIG. 1 illustrates a cross-sectional view of one embodiment of the present invention where a die is secured to the die pad with silver filled adhesive polymer. The thickness of the adhesive between the bottom surface of the die and the top surface of the die pad is relatively uniform across the entire width of the die. The bottom surface of the die includes a plurality of cavities containing silver nanoparticles.

The bond between the silver filled adhesive polymer and the back of the die containing silver particles is obtained, by curing the adhesive polymer at a temperature wherein the silver particles in the back side of the die and the silver filling in the polymer are sintered together to form a silver die bond. Cure temperature is typically 180° C. or above.

Sintering between embedded silver nanomaterials and silver fillers in the adhesive polymer enhance the electrical and thermal performance of the assembly. Meanwhile, the increase of bonding area and mechanical interlocking between die backside and adhesive polymer can substantially increase the adhesion at the interface, thus enabling enhanced package performance and reliability.

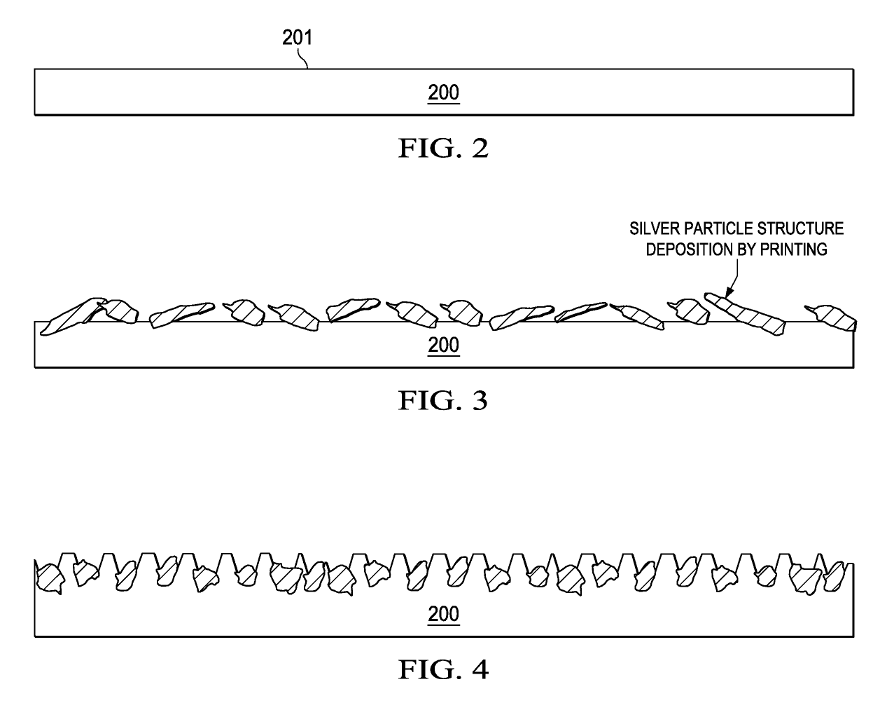

Embodiments of the present invention will now be described with reference to FIGS. 2-6. A particular embodiment of regions around and pertaining to the die, die attach material and die pad will be described. More particularly, delamination and poor electrical and thermal performance are mainly located at the die and die attach material interface. Increasing the percentage of silver filler in the die attach material can improve the thermal performance but it has its limitations. As the percentage of silver fillers increases, the viscosity will significantly increase and cause manufacturability issues such as poor dispensing performance. Moreover, high filler percentage will increase the modulus of the adhesive polymers and result in high stresses and delamination at the interface. Sintering of the silver particles embedded in the die to the silver particle in the die attachment material is key to enhancing electrical and thermal performance, and the structure produced on die backside will effectively prevent delamination at the die-die attachment material interface. The delamination at the interface will considerably decrease the thermal performance. Therefore, improving the adhesion at the interface will, in turn, enhances the electrical and thermal performance under stressed conditions.

FIG. 2 is an exemplary sample of a semiconductor wafer 200 having top and backside 201 surfaces.

FIG. 3 illustrates application of silver nanomaterials to the backside 201 of the wafer 200. Application can be accomplished in a variety of methods. In this particular embodiment, the particles are applied by printing a silver ink, which is commercially available, onto the backside of the wafer. The ink is then dried to evaporate the volatile suspension vehicle.

FIG. 4 shows that silver nanoparticles etch down into wafer from wafer backside surface by Metal-assisted Chemical Etching.

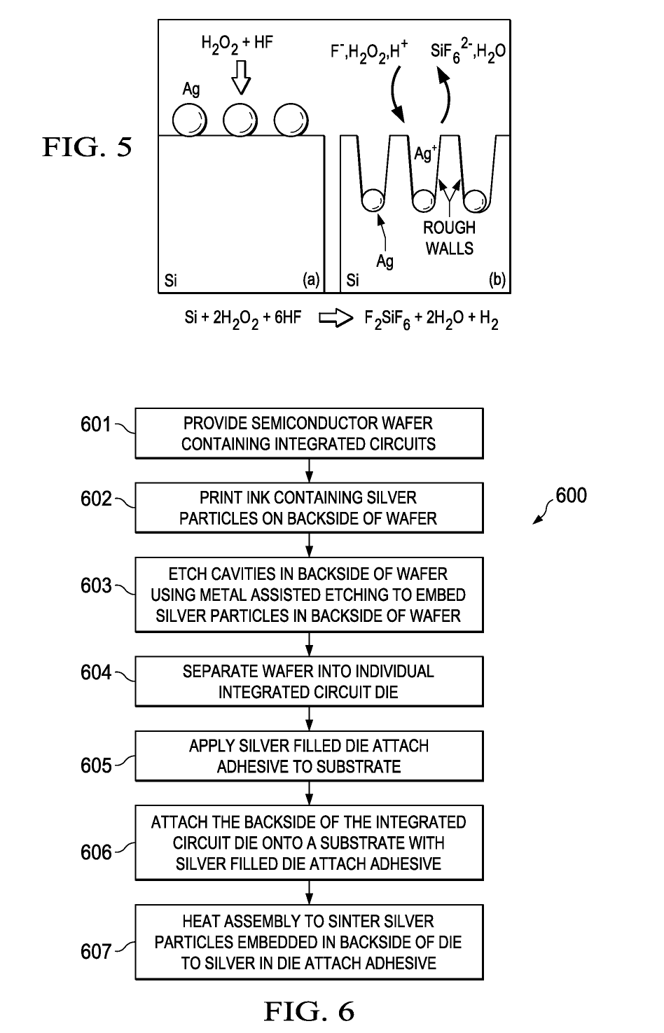

FIG. 5 is a diagramtic illustration of the Metal-assisted Chemical Etching process. Metal-assisted Chemical Etching is typically conducted by immersing the wafer into an etchant composed of HF and H₂O₂ or applying an etchant onto the wafer backside. The active side of circuits can be protected with thin polymer films. It is important that silver nanomateirals should be remained on top surface to allow the sintering between silver nanomaterials and silver fillers in adhesive polymers to occur. In this particular embodiment, the etching is accomplished using the chemical reaction:

Si+2H₂O₂+6HF→H₂SiF₆+2H₂O+H₂

As shown in the illustration in FIG. 5, a metal catalyst (silver) and a semiconductor interface for a cathode and anode, respectively. Through the metal catalyst, charge injection is sustained from a solution to the substrate and charge is balanced by the cathodic and anodic reactions. The presence of a local site for reaction (the silver nanoparticle) defines the selectivity of the etching mechanism.

Referring next to the flow chart 600 presented in FIG. 6, one suitable approach for forming a package having good electrical and thermal performance and low delamination at die-die attach interface_will be described. Unless explicitly indicated otherwise, the operations described below may be performed concurrently or in any order. Operations may be added to or removed from flow chart 600.

Step 601 involves providing a semiconductor wafer containing integrated circuit die, having a top side and a bottom side.

Step 602 involves depositing silver particles on the backside of the semiconductor wafer utilizing a printing process wherein the printing process prints ink containing silver particles on the wafer. The ink is then dried to allow the suspension vehicle in the ink to evaporate leaving the silver particles on the backside of the wafer, wherein the silver can be in the form of nanoparticles, nanowires, nanoflakes or silver particles.

Step 603 involves etching cavities in backside of wafer using metal assisted etching to embed silver nanoparticles in backside of wafer. The cavities formed in the backside of the wafer are typically less than 5 um deep.

Step 604 involves separating the die using any a method selected from sawing, scribing and breaking or laser cutting.

Step 605 involves depositing a relatively uniform layer of silver filled adhesive polymer to a substrate. The substrate can be a lead frame, a laminate or a ceramic package, wherein the silver can be in the form of nanoparticles, nanowires, nanoflakes or silver particles.

Step 606 involves attaching the backside of integrated circuit die onto a substate using die attach adhesives while maintaining the top surface of the die in a parallel with the top surface of the substrate.

Step 607 involves heating the assembly to sinter nanoparticles embedded in backside of die to silver in die attach adhesive

Die attach with high thermal conductivity and solver sinterable die attach are very expensive. Engineering the interface between die and die attach is effective to improve electrical and thermal performance of packages. Sintering and improving the adhesion at interface described herein will enable the use of low cost die attach materials to reduce interfacial electrical and thermal resistances effectively for packages where electrical and thermal performances are needed.

While various embodiments of the present invention have been described above, it should be understood that they have been presented by way of example only and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

What is claimed is:

1. An apparatus, comprising:
a semiconductor die, having a top side and a backside;
a plurality of cavities in the back side of the semiconductor die, wherein each of the plurality of cavities contains an embedded silver structure;
a substrate, having a top side and a backside;
a substantially uniform layer of silver filled die attach adhesive on the top side of the substrate;
wherein the backside of integrated circuit die is positioned on die attach adhesive while maintaining the top surface of the die in a parallel with the top surface of the substrate; and
wherein the semiconductor die is mechanically attached to the substrate by sintering the silver particles embedded in backside of die to the silver in die attach adhesive.

2. The apparatus of claim 1 wherein, the silver filled die attach adhesive is a polymer with a silver fillers, wherein the silver fillers are selected from the group of silver nanoparticles, nanowires, nanoflakes or silver particles.

3. The apparatus of claim 1 wherein the silver particles embedded in backside of die are selected from the group of silver nanoparticles, nanowires, nanoflakes or silver particles

4. The apparatus of claim 1, wherein the substrate is selected from the group of leadframe, a laminated substrate or a ceramic substrate.

5. A method of attaching a semiconductor die to a substrate, comprising the steps;
providing a semiconductor wafer containing integrated circuits, wherein the wafer has a top side and a backside;
printing an ink containing silver particles to the back side of the wafer;
etching a plurality of cavities on the backside of the wafers using metal assisted chemical etching to embed silver particles in the plurality of cavities in the backside of the wafer;
separating the semiconductor wafer into individual integrated circuit die;
providing a substrate, having a top side and a backside;
applying a substantially uniform layer of silver particle filled adhesive to the top side of the substrate;
positioning the backside of integrated circuit die on the die attach adhesive while maintaining the top surface of the die in a parallel with the top surface of the substrate; and
sintering the silver particles embedded in backside of die to the silver in die attach adhesive to mechanically attach the integrated circuit die to the substrate.

6. The method of claim 5, wherein, the silver filled die attach adhesive is a polymer with a silver filler wherein the silver filler is selected from the group of silver nanoparticles, nanowires, nanoflakes or silver particles.

7. The method of claim 5, wherein the silver particles embedded in backside of die are selected from the group of silver nanoparticles, nanowires, nanoflakes or silver particles

8. The method of claim 5, wherein the substrate is selected from the group of a lead frame, a laminate substrate or a ceramic substrate.
